(19) United States
(12) Patent Application Publication
(10) Pub. No.: US 2026/0047221 A1
(43) Pub. Date: Feb. 12, 2026

(54) PHOTODETECTION DEVICE

(71) Applicant: SONY SEMICONDUCTOR SOLUTIONS CORPORATION, KANAGAWA (JP)

(72) Inventors: Yukari TAGUCHI, KANAGAWA (JP); Shinichiro NOUDO, KANAGAWA (JP); Yoshiaki MASUDA, KANAGAWA (JP); Keisuke TERADA, KANAGAWA (JP)

(21) Appl. No.: 19/104,258

(22) PCT Filed: Aug. 8, 2023
(86) PCT No.: PCT/JP2023/028854

§ 371 Date: Feb. 17, 2025

(30) Foreign Application Priority Data
Aug. 22, 2022 (JP) 2022-131489

(51) Int. Cl. H10F 39/00

(52) U.S. Cl. CPC H10F 39/8063; H10F 39/8023; H10F 39/8053

(57) ABSTRACT

The present technology relates to a photodetection device capable of suppressing occurrence of flare and ghost.

Provided are: a photoelectric conversion unit; a first pixel including a first light condensing unit that condenses light on the photoelectric conversion unit; a second pixel including a second light condensing unit having a shape different from a shape of the first light condensing unit; and a pixel array unit in which the first pixel and the second pixel are arranged in a matrix, in which the second pixel is randomly arranged in the pixel array unit. The present technology can be applied to a photodetection device that detects light.

### TECHNICAL FIELD

The present technology relates to a photodetection device, and for example, relates to a photodetection device capable of capturing an image while suppressing occurrence of flare and ghost.

### BACKGROUND ART

In recent years, in digital video cameras and digital still cameras, there has been a demand for high resolving power that captures fine details of a subject and downsizing of apparatuses focusing on portability. In addition, in imaging devices, development for downsizing the pixel size has been conducted while maintaining the imaging characteristics.

In addition to the continuous demand for high resolution and miniaturization, there is an increasing demand for improvement of the minimum subject illuminance, high-speed imaging, and the like, and in order to realize the improvement, expectations for comprehensive image quality improvement including the SN ratio are also growing in imaging devices. Patent Document 1 proposes to improve image quality by reducing optical color mixing and flare by forming a light shielding film formed on a pixel boundary of a light receiving surface via an insulating layer.

### CITATION LIST

### Patent Document

Patent Document 1: Japanese Patent Application Laid-Open No. 2010-186818

### SUMMARY OF THE INVENTION

### Problems to be Solved by the Invention

As described above, measures for suppressing the occurrence of flare, ghost, and the like have been conventionally taken, but the suppression effect is not sufficient, and it is required to take measures with a higher suppression effect.

The present technology has been made in view of such a situation, and an object thereof is to suppress occurrence of flare and ghost.

### Solutions to Problems

A first photodetection device according to one aspect of the present technology is a photodetection device including: a photoelectric conversion unit; a first pixel including a first light condensing unit that condenses light on the photoelectric conversion unit; a second pixel including a second light condensing unit having a shape different from a shape of the first light condensing unit; and a pixel array unit in which the first pixel and the second pixel are arranged in a matrix, in which the second pixel is randomly arranged in the pixel array unit.

A second photodetection device according to one aspect of the present technology is a photodetection device including: a photoelectric conversion unit; a light condensing unit that condenses light on the photoelectric conversion unit; a pixel including the light condensing unit; and a pixel array unit in which the pixels are arranged in a matrix, in which the light condensing unit includes a first member and a second member, a first period in which the first member is arranged and a second period in which the second member is arranged are different in the pixel array unit, and the second period is longer than the first period.

In a first photodetection device according to one aspect of the present technology, provided are: a photoelectric conversion unit; a first pixel including a first light condensing unit that condenses light on the photoelectric conversion unit; a second pixel including a second light condensing unit having a shape different from a shape of the first light condensing unit; and a pixel array unit in which the first pixel and the second pixel are arranged in a matrix, in which the second pixel is randomly arranged in the pixel array unit.

In a second photodetection device according to one aspect of the present technology, provided are: a photoelectric conversion unit; a light condensing unit that condenses light on the photoelectric conversion unit; a pixel including the light condensing unit; and a pixel array unit in which the pixels are arranged in a matrix, in which the light condensing unit includes a first member and a second member, a first period in which the first member is arranged and a second period in which the second member is arranged are different in the pixel array unit, and the second period is longer than the first period.

Note that the photodetection device may be an independent device or an internal block constituting one device.

### BRIEF DESCRIPTION OF DRAWINGS

FIG. 1 is a diagram illustrating a schematic configuration of a photodetection device according to the present disclosure.

FIG. 2 is a diagram for explaining a planar configuration example of an imaging device.

FIG. 3 is a diagram for explaining a cross-sectional configuration example of an imaging device.

FIG. 4 is a diagram for explaining a principle of occurrence of flare and ghost.

FIG. 5 is a diagram for explaining a cell size and a diffraction angle.

FIG. 6 is a diagram for explaining a relationship between a cell size and reflectance.

FIG. 7 is a diagram for explaining a configuration of an imaging device in a first embodiment.

FIG. 8 is a diagram for explaining a configuration of the imaging device in the first embodiment.

FIG. 9 is a diagram for explaining a configuration of a block.

FIG. 10 is a diagram for explaining a configuration of a block.

FIG. 11 is a diagram illustrating a verification result.

FIG. 12 is a diagram illustrating a verification result.

FIG. 13 is a diagram for explaining a configuration of an imaging device in a second embodiment.

FIG. 14 is a diagram for explaining a configuration of an imaging device in a third embodiment.

FIG. 15 is a diagram for explaining a configuration of an imaging device in a fourth embodiment.

FIG. 16 is a diagram for explaining a configuration of an imaging device in a fifth embodiment.

FIG. 17 is a diagram for explaining a configuration of an imaging device in a sixth embodiment.

FIG. 18 is a diagram for explaining a configuration of an imaging device in a seventh embodiment.

FIG. 19 is a diagram for explaining a configuration of an imaging device in an eighth embodiment.

FIG. 20 is a diagram for explaining a configuration of an imaging device in a ninth embodiment.

FIG. 21 is a diagram for explaining a configuration of a trench in the ninth embodiment.

FIG. 22 is a diagram illustrating a configuration example of an electronic apparatus.

FIG. 23 is a view depicting an example of a schematic configuration of an endoscopic surgery system.

FIG. 24 is a block diagram depicting an example of a functional configuration of a camera head and a camera control unit (CCU).

FIG. 25 is a block diagram depicting an example of schematic configuration of a vehicle control system.

FIG. 26 is a diagram of assistance in explaining an example of installation positions of an outside-vehicle information detecting section and an imaging section.

### MODE FOR CARRYING OUT THE INVENTION

Hereinafter, modes (hereinafter, referred to as embodiments) for implementing the present technology will be described.

### <Schematic Configuration Example of Imaging Device>

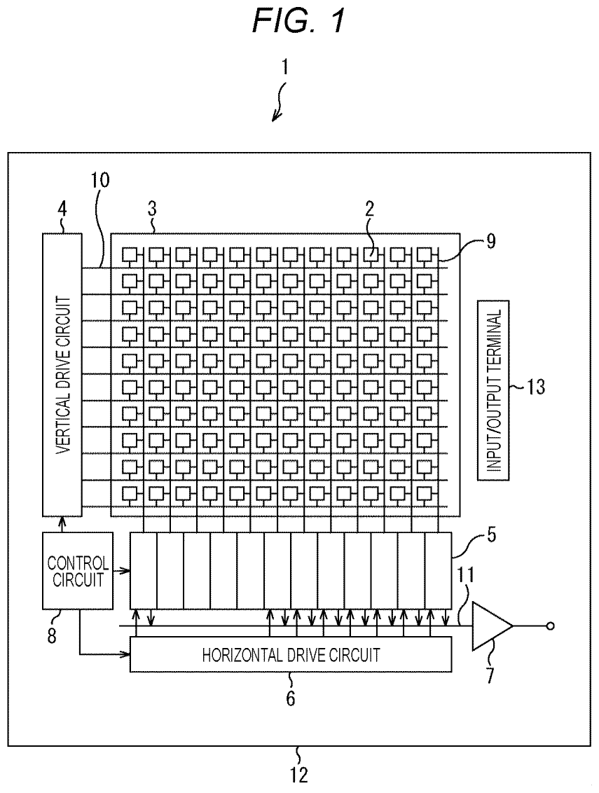

FIG. 1 illustrates a schematic configuration of an imaging device according to the present disclosure. The present technology can be applied to an imaging device that captures an image (capturing device that performs color imaging), a distance measuring device that measures a distance to a subject, and the like. In the following description, an imaging device that captures a color image will be described as an example, but the present invention can be widely applied to a photodetection device that receives light and detects the amount of light.

An imaging device 1 of FIG. 1 includes a pixel array unit 3 in which pixels 2 are arranged in a two-dimensional array and a peripheral circuit unit around the pixel array unit 3 on a semiconductor substrate 12 using, for example, silicon (Si) as a semiconductor. The peripheral circuit unit includes a vertical drive circuit 4, a column signal processing circuit 5, a horizontal drive circuit 6, an output circuit 7, a control circuit 8, and the like.

The pixel 2 includes a photodiode as a photoelectric conversion element and a plurality of pixel transistors. The plurality of pixel transistors includes four MOS transistors, which are a transfer transistor, a selection transistor, a reset transistor, and an amplification transistor, for example.

In addition, the pixel 2 may also have a shared pixel structure. This pixel sharing structure includes a plurality of photodiodes, a plurality of transfer transistors, one shared floating diffusion (floating diffusion region), and one shared other pixel transistor. That is, the shared pixel is configured such that the photodiodes and the transfer transistors constituting a plurality of unit pixels share other pixel transistors, respectively.

The control circuit 8 receives an input clock and data instructing an operation mode or the like, and outputs data such as internal information of the imaging device 1. That is, the control circuit 8 generates a clock signal and a control signal which serve as a reference for operation of the vertical drive circuit 4, the column signal processing circuit 5, the horizontal drive circuit 6, and the like on the basis of a vertical synchronization signal, a horizontal synchronization signal, and a master clock. Then, the control circuit 8 outputs the generated clock signal and control signal to the vertical drive circuit 4, the column signal processing circuit 5, the horizontal drive circuit 6, and the like.

The vertical drive circuit 4 is constituted by a shift register, for example, selects a pixel drive line 10, supplies a pulse for driving the pixel 2 to the selected pixel drive line 10, and drives the pixels 2 in units of rows. That is to say, the vertical drive circuit 4 sequentially selects to scan the pixels 2 in the pixel array unit 3 in units of rows in a vertical direction and supplies a pixel signal based on a signal charge generated according to a received light amount by a photoelectric conversion unit of each pixel 2 to the column signal processing circuit 5 through a vertical signal line 9.

The column signal processing circuit 5 arranged for each column of the pixels 2 performs signal processing such as noise removal on the signals output from the pixels 2 of one column for each pixel column. For example, the column signal processing circuit 5 performs signal processing such as correlated double sampling (CDS) for removing a fixed pattern noise specific to the pixel and AD conversion.

The horizontal drive circuit 6 is constituted by a shift register, for example, sequentially selects each of the column signal processing circuits 5 by sequentially outputting horizontal scanning pulses and outputs the pixel signal from each of the column signal processing circuits 5 to a horizontal signal line 11.

The output circuit 7 performs signal processing on the signals sequentially supplied from each of the column signal processing circuits 5 through the horizontal signal line 11 and outputs the processed signals. For example, there is a case where the output circuit 7 performs only buffering, or a case where the output circuit 7 performs black level adjustment, column variation correction, various types of digital signal processing, and the like. An input/output terminal 13 communicates signals with the outside.

The imaging device 1 configured as described above is a CMOS image sensor called a column AD system in which the column signal processing circuits 5 that perform CDS processing and AD conversion processing are arranged for each pixel column.

Furthermore, the imaging device 1 is a back-illuminated MOS imaging device in which light is incident from the back surface side opposite to the front surface side of the semiconductor substrate 12 on which the pixel transistors are formed.

### <Plane and Cross-Sectional Configuration Example of Imaging Device>

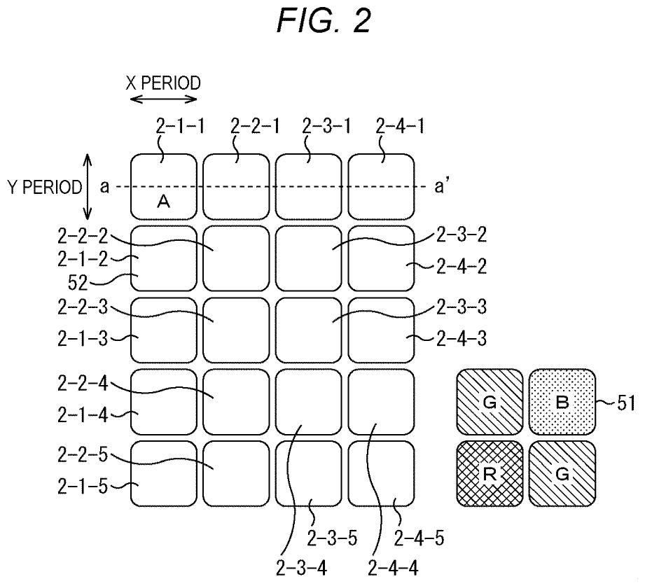

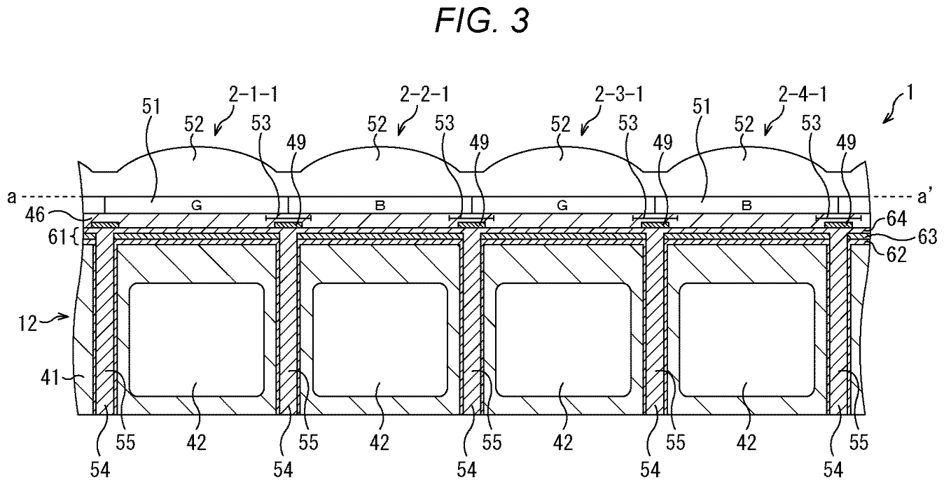

The left diagram of FIG. 2 illustrates 20 pixels 2 of 4×5 arranged in the pixel array unit 3, and the right diagram illustrates an arrangement example of a color filter 51 (FIG. 3). FIG. 3 is a diagram illustrating a cross-sectional configuration example of pixels 2 along a line segment a-a′ in FIG. 2.

Referring to the cross-sectional configuration example in FIG. 3, the imaging device 1 includes the semiconductor substrate 12, a multilayer wiring layer formed on the front surface side, and a support substrate (both are not illustrated).

The semiconductor substrate 12 is constituted by, for example, silicon (Si), and is formed to have a thickness of, for example, 1 to 6 μm. In the semiconductor substrate 12, for example, an N-type (second conductivity type) semiconductor region 42 is formed for each pixel 2 in a P-type (first conductivity type) semiconductor region 41, whereby the photodiode PD is formed in units of pixels. The P-type semiconductor region 41 provided on both the front and back surfaces of the semiconductor substrate 12 also serves as a hole charge accumulation region for dark current suppression.

As illustrated in FIG. 3, the imaging device 1 is configured by laminating an antireflection film 61, a transparent insulating film 46, a color filter 51, and an on-chip lens 52 on the semiconductor substrate 12 in which the N-type semiconductor region 42 constituting a photodiode PD is formed for each pixel 2.

An antireflection film 61 for preventing reflection of incident light is formed at an interface (light-receiving-surface-side interface) of the P-type semiconductor region 41 on the upper side of the N-type semiconductor region 42 serving as a charge accumulation region.

The antireflection film 61 has, for example, a laminated structure in which a fixed charge film and an oxide film are laminated, and for example, an insulating thin film having a high dielectric constant (High-k) by an atomic layer deposition (ALD) method can be used. Specifically, hafnium oxide (HfO₂), aluminum oxide (Al₂O₃), titanium oxide (TiO₂), strontium titan oxide (STO), or the like can be used. In the example of FIG. 3, the antireflection film 61 is configured by laminating a hafnium oxide film 62, an aluminum oxide film 63, and a silicon oxide film 64.

Furthermore, a light shielding film 49 is formed between the pixels 2 so as to be laminated on the antireflection film 61. As the light shielding film 49, a single-layer metal film such as titanium (Ti), titanium nitride (TiN), tungsten (W), aluminum (Al), or tungsten nitride (WN) is used. Alternatively, a laminated film (for example, a laminated film of titanium and tungsten, a laminated film of titanium nitride and tungsten, or the like) of these metals may be used as the light shielding film 49.

The transparent insulating film 46 is formed on the entire back surface side (light incident surface side) of the P-type semiconductor region 41. The transparent insulating film 46 is a material that transmits light and has insulating properties, and has a refractive index n1 smaller than the refractive index n2 of the semiconductor regions 41 and 42 (n1<n2). Examples of the material of the transparent insulating film 46 include silicon oxide (SiO₂), silicon nitride (SiN), silicon oxynitride (SiON), hafnium oxide (HfO₂), aluminum oxide (Al₂O₃), zirconium oxide (ZrO₂), tantalum oxide (Ta₂O₅), titanium oxide (TiO₂), lanthanum oxide (La₂O₃), praseodymium oxide (Pr₂O₃), cerium oxide (CeO₂), neodymium oxide (Nd₂O₃), promethium oxide (Pm₂O₃), samarium oxide (Sm₂O₃), europium oxide (Eu₂O₃), gadolinium oxide (Gd₂O₃), terbium oxide (Tb₂O₃), dysprosium oxide (Dy₂O₃), and holmium oxide (Ho₂O₃), thulium oxide (Tm₂O₃), ytterbium oxide (Yb₂O₃), lutetium oxide (Lu₂O₃), yttrium oxide (Y₂O₃), a resin, and the like can be used alone or in combination.

The color filter 51 is formed on the upper side of the transparent insulating film 46 including the light shielding film 49. The color filter 51 of Red, Green, or Blue is formed for each pixel. The color filter 51 is formed by spin coating a photosensitive resin containing a dye such as a pigment or a dye. Each color of Red, Green, and Blue is arranged by, for example, a Bayer array, but may be arranged by other arrangement methods. In the example of FIG. 3, a Green (G) color filter 51 is formed in the pixel 2-1-1 and the pixel 2-3-1, and a blue (b) color filter 51 is formed in the pixel 2-2-1 and the pixel 2-4-1.

Referring to the right diagram in FIG. 2, the color filters 51 are arranged in a Bayer array, and in the figure, a green (G) color filter 51 is arranged at the upper left, a blue (B) color filter 51 is arranged at the upper right, a red (R) color filter 51 is arranged at the lower left, and a B (G) color filter 51 is arranged at the lower right. In a case where the four 2×2 color filters 51 illustrated in the right diagram of FIG. 2 are set as one unit, a plurality of units is continuously arranged in the pixel array unit 3 in the vertical direction and the horizontal direction.

Referring to the cross-sectional configuration of the pixels 2 illustrated in FIG. 3, the on-chip lens 52 is formed for each pixel 2 on the upper side of the color filter 51. The on-chip lens 52 is constituted by, for example, a resin material such as a styrene resin, an acrylic resin, a styrene-acrylic copolymer resin, or a siloxane resin. The incident light is condensed in the on-chip lens 52, and the condensed light is efficiently incident on the photodiode PD via the color filter 51.

Referring to the left diagram of FIG. 2, the on-chip lens 52 is arranged on each pixel 2. In a case where the quadrangle illustrated in the left diagram of FIG. 2 also represents the shape of the on-chip lens 52, the on-chip lenses 52 having the same shape are arranged on the respective pixels 2.

Referring to the cross-sectional configuration example of the pixel 2 illustrated in FIG. 3, in the pixel 2, an inter-pixel isolation portion 54 that isolates the pixels 2 from each other is formed on the semiconductor substrate 12. The inter-pixel isolation portion 54 is formed by forming a trench penetrating the semiconductor substrate 12 between the N-type semiconductor regions 42 constituting the photodiode PD, forming the aluminum oxide film 63 on the inner surface of the trench, and further embedding an insulator 55 in the trench when the silicon oxide film 64 is formed.

Note that a portion of the silicon oxide film 64 filled in the inter-pixel isolation portion 54 may be filled with polysilicon. FIG. 3 illustrates a case where the silicon oxide film 64 is formed integrally with the insulator 55.

By configuring such an inter-pixel isolation portion 54, the adjacent pixels 2 are electrically completely isolated from each other by the insulator 55 embedded in the trench. As a result, it is possible to prevent the charge generated inside the semiconductor substrate 12 from leaking to the adjacent pixels 2.

### <Occurrence of Ghost and Flare>

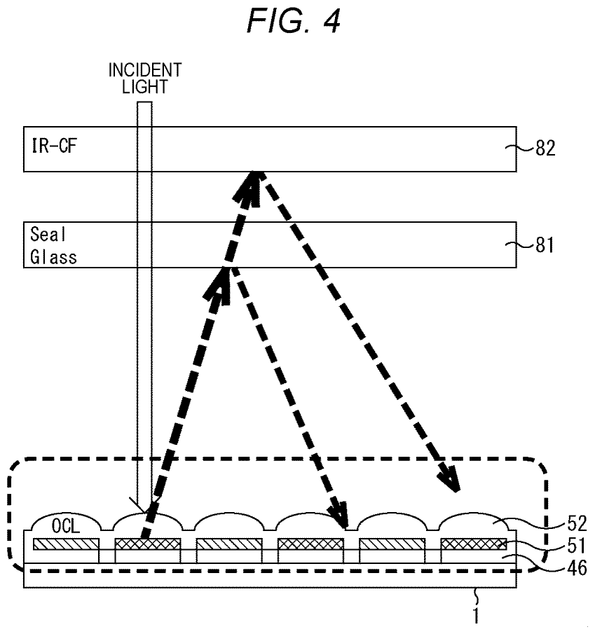

A cause of image quality degradation called ghost, flare, or the like will be described with reference to FIG. 4.

As illustrated in FIG. 4, a seal glass 81 and an infrared cut filter 82 are arranged on the light incident surface side of the imaging device 1. The light incident on the imaging device 1 generates diffracted reflected light having a certain diffraction order (m) and a certain diffraction reflection angle (θ) according to the formation pitch of the surface of the on-chip lens 52.

The diffracted reflected light is reflected by the seal glass 81 formed above the imaging element and becomes reflected light having a visible light component. In addition, the light component having passed through the seal glass is reflected by the infrared cut filter 82 formed further above the seal glass 81, and becomes reflected light having a large amount of red components in the visible light region.

The light reflected by the seal glass 81 and the infrared cut filter 82 travels toward the imaging element again, and a part of the component is photoelectrically converted by the photodiode 42 of the imaging element. This may cause ghost or flare, which may degrade the image quality of the imaging device 1.

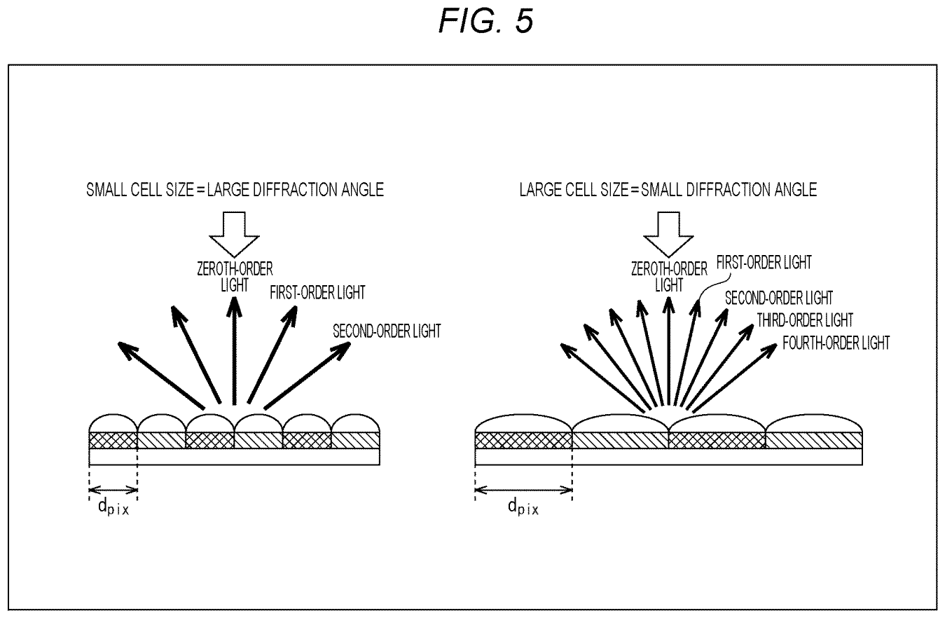

FIG. 5 is a diagram for explaining the relationship between the size of the pixels 2 and the diffraction angle. FIG. 5 illustrates an example in which the pitch of the pixels 2 and the formation pitch of the on-chip lenses 52 are formed to be equal.

The diffraction order (m) and the diffraction angle (θ) of the diffracted reflected light can be expressed by the following Formula (1).

$$d \times sin θ = m \times λ \qquad ( 1 )$$

In Formula (1), d is a pixel size (described as a cell size), and λ is a wavelength of incident light. From Formula (1), it can be read that in a case where λ is constant, the diffraction order m decreases as the cell size, which is the formation pitch of the on-chip lens, decreases, and the diffraction order m increases as the cell size increases.

Although the formation pitch of the on-chip lens is the cell size, it can be said that the periodicity is small when the cell size is small, and the periodicity is also large when the cell size is large. In other words, it can be read that the diffraction order m decreases as the periodicity decreases (the state in the left diagram in FIG. 5), and the diffraction order m increases as the periodicity increases (the state in the right diagram in FIG. 5).

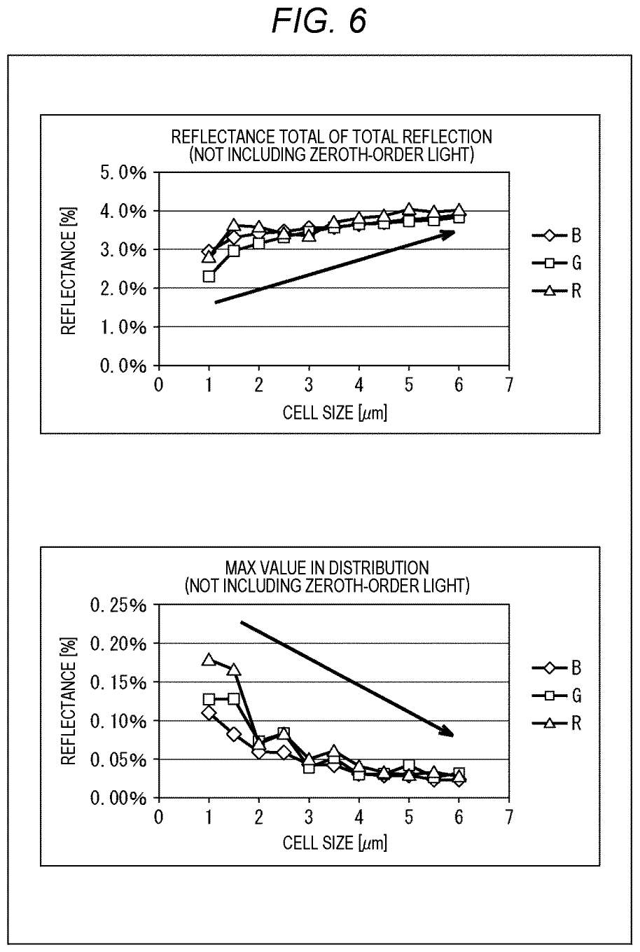

This is represented by the graph illustrated in FIG. 6. The horizontal axis of the graph illustrated in FIG. 6 represents the cell size, and the vertical axis represents the reflectance. The upper graph of FIG. 6 is a graph representing the total of total reflection not including zeroth-order light, and the lower graph is a graph representing the maximum value in the distribution not including zeroth-order light. In FIG. 6, a graph represented by a triangle represents reflectance when red (R) is incident, a graph represented by a square represents reflectance when green (G) is incident, and a graph represented by a diamond represents reflectance when B color (blue) is incident.

From the graph illustrated above in FIG. 6, it can be understood that the total value of the reflection tends to increase as the cell size increases, in other words, as the periodicity increases, regardless of the color of the incident light.

From the graph illustrated in the lower part of FIG. 6, it can be seen that the intensity of the reflected light converging to one of the diffracted orders (specific angle) tends to decrease as the cell size increases, in other words, as the periodicity increases, regardless of the color of the incident light. In other words, it can be understood that when the cell size is small, the periodicity tends to decrease, and the intensity of reflected light converging on one of the diffracted orders (specific angle) tends to increase.

From these facts, it can be understood that it is effective to increase the cell size and increase the periodicity in order to suppress occurrence of flare and ghost. However, in recent years, there is an increasing need for miniaturization and higher pixel density of the pixels 2, and it is desired to suppress occurrence of flare and ghost other by means than increasing the cell size. Therefore, the imaging device 1 that suppresses occurrence of flare and ghost by increasing the periodicity without increasing the cell size will be described below.

<Imaging Device in which Structural Parts are Randomly Arranged>

The imaging device 1 capable of reducing strong reflection intensity at a specific angle and suppressing image quality degradation due to flare and ghost by increasing the periodicity of the pixels 2 will be described.

In order to increase the periodicity of the pixels 2, structures constituting the pixels 2 are randomly arranged. As described below, the structure includes the on-chip lens 52, the color filter 51, a recessed region 48, a reflective film 131, a trench 151, and the like. The periodicity will be described again with reference to FIG. 2.

The left diagram in FIG. 2 schematically illustrates the on-chip lens 52 arranged on the pixel 2, but the on-chip lenses 52 arranged on the pixel 2 are all configured in the same shape. The period of the on-chip lens 52 in this case is represented as a (1×1) period. The numerical value before the multiplication in parentheses of the (1×1) period represents a period in the X direction (horizontal direction), and the numerical value after the multiplication represents a period in the Y direction (vertical direction).

The color filter 51 arranged on the pixels 2 illustrated in the right diagram of FIG. 2 has repetition of green (G) and blue (B), that is, two periods in the X direction. In the Y-axis direction, it repeats as green (G) and red (R), or as blue (B) and green (G), with both cases corresponding to two periods. Therefore, the color filter 51 has a (2×2) period.

Since the on-chip lens 52 of the imaging device 1 illustrated in FIG. 2 has a (1×1) period and the color filter 51 has a (2×2) period, the period of the light condensing structure including the on-chip lens 52 and the color filter 51 of the imaging device 1 is a (2×2) period. The light condensing structure is a structure related to light condensing in the structure of the imaging device 1, and is a structure formed mainly between the on-chip lens 52 and a wiring layer (not illustrated).

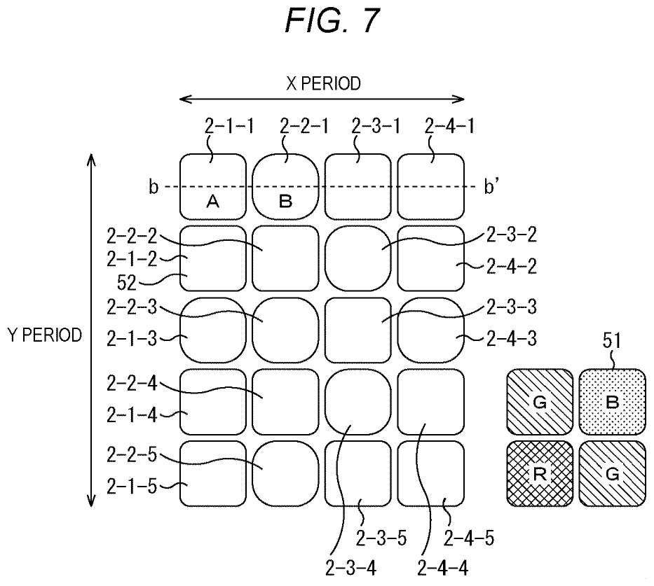

In order to increase the period of the light condensing structure of the imaging device 1, it is conceivable to increase the period of the on-chip lens 52 and/or increase the period of the color filter 51. Therefore, in FIG. 7, a case where the period of the on-chip lens 52 included in the light condensing structure is increased will be described.

Similarly to FIG. 2, FIG. 7 is a diagram in which the on-chip lens 52 arranged on the pixels 2 arranged in the pixel array unit 3 is illustrated in the left diagram, and the color filter 51 is illustrated in the right diagram. The arrangement of the color filters 51 is RGB arrangement as in the case illustrated in FIG. 2, and is an arrangement in which four pixels of 2× 2 are repeated as one unit. That is, in this case, the period of the color filter 51 is a (2×2) period.

Referring to the left diagram in FIG. 7, in the on-chip lens 52, on-chip lenses 52 having two types of shapes are mixed in a plan view, one has the same shape as the pixel 2, and the other has a shape different from the pixel 2. In a case where the pixel 2 has a quadrangular shape in plan view, the on-chip lens 52 can be either an on-chip lens formed in a quadrangular shape or an on-chip lens formed in a shape other than the quadrangular shape.

In FIG. 7, an on-chip lens formed in a quadrangular shape is referred to as an on-chip lens 52A, and an on-chip lens formed in a shape other than the quadrangular shape is referred to as an on-chip lens 52B.

It is assumed that the on-chip lens 52A is arranged in greater numbers than the on-chip lens 52B, and the on-chip lens 52A has higher light condensing performance than the on-chip lens 52B. Basically, the on-chip lenses 52A are arranged in the pixel array unit 3, but the on-chip lenses 52B are randomly arranged.

Since the on-chip lenses 52B are randomly arranged in the pixel array unit 3, the periodicity of the on-chip lenses 52 on the pixel array unit 3 can be increased. Referring to FIG. 2 for comparison, in the example illustrated in FIG. 2, only the on-chip lenses 52A are arranged on the pixel array unit 3, resulting in a (1×1) period. In the example illustrated in FIG. 7, not only the on-chip lenses 52A but also the on-chip lenses 52B are arranged on the pixel array unit 3, so that this period can be changed. Furthermore, the arrangement itself of the on-chip lenses 52B is also randomly arranged, so that the period can be increased.

In the example illustrated in FIG. 7, among the 20 pixels of 4×5, the on-chip lenses 52B are arranged in seven pixels 2 of the pixel 2-2-1, the pixel 2-3-2, the pixel 2-1-3, the pixel 2-2-3, the pixel 2-4-3, the pixel 2-3-4, and the pixel 2-2-5.

When the entire pixel array unit 3 is viewed, the positions at which the on-chip lenses 52B are arranged are random. Although random, the on-chip lenses 52B are not collectively arranged, and are arranged to be scattered on the pixel array unit 3 to some extent. By randomly arranging the on-chip lens 52B having a shape different from that of the on-chip lens 52A, the period can be changed to a period other than the (1×1) period, and the period can be changed to be large.

However, it is assumed that there is a difference in light condensing performance due to a difference in the shape of the on-chip lens 52. The shape of the on-chip lens 52B is set such that there is no difference (no influence) in optical characteristics such as sensitivity and oblique incidence characteristics between the pixel 2 in which the on-chip lens 52A is arranged and the pixel 2 in which the on-chip lens 52B is arranged, or the difference falls within an allowable range.

Alternatively, in a case where a difference occurs in characteristics between the pixel 2 in which the on-chip lens 52A is arranged and the pixel 2 in which the on-chip lens 52B is arranged, in signal processing in the subsequent stage, a signal from the pixel 2 in which the on-chip lens 52B is arranged may be corrected to reduce the difference.

Since the shape of the on-chip lens 52 is different, the characteristics of the pixel 2 may change. In a case where correction is performed in the subsequent stage, the positions where the on-chip lenses 52B are arranged are set in advance, and the pixels 2 to be corrected need to be specified. Therefore, the arrangement of the on-chip lenses 52B may have a certain degree of regularity, and the positions where the on-chip lenses 52B are arranged may be specified.

Even if the on-chip lenses 52B are arranged with a certain degree of regularity, the on-chip lenses are randomly arranged and arranged so that the period is also (1×1) period or more when the pixel array unit 3 is viewed.

In the example illustrated in FIG. 7, 15 pixels having a (3×5) period in which the period in the X direction is 3 periods and the period in the Y direction is 5 periods are defined as one block. The pixel array unit 3 is repeatedly arranged in the vertical direction and the horizontal direction in units of blocks of this (3×5) period. In this case, since the period of the on-chip lens 52 is a (3×5) period and the period of the color filter 51 is a (2×2) period, the period of the light condensing structure including the on-chip lens 52 and the color filter 51 is a (6×10) period. The X period is 6 periods of 3×2, and the Y period is 10 periods of 5×2.

In the example illustrated in FIG. 2, the period of the light condensing structure is a (2×2) period, but in the example illustrated in FIG. 7, the period is a (6×10) period, and it can be seen that the period has increased. As described with reference to FIGS. 4 to 6, since flare and ghost can be suppressed by increasing the period, flare and ghost can be suppressed according to the structure illustrated in FIG. 7.

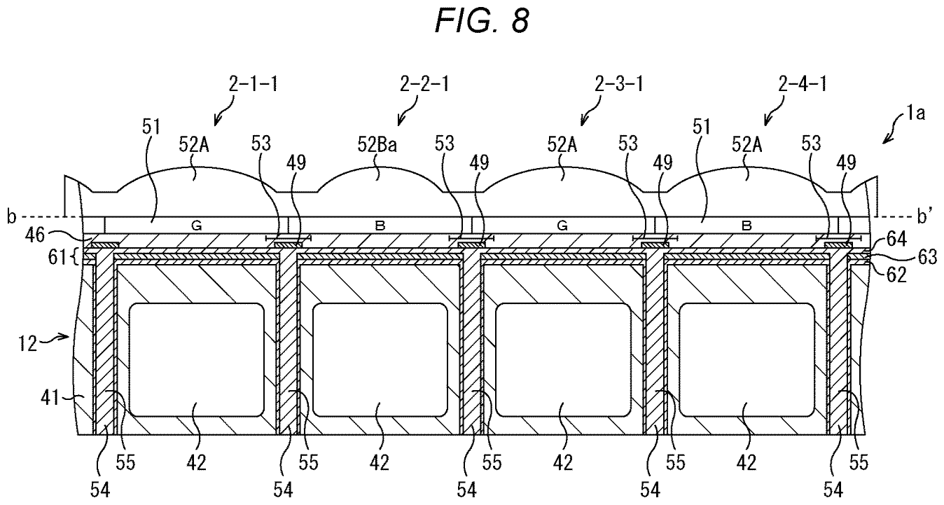

FIG. 8 is a diagram illustrating a cross-sectional configuration example of pixels 2 along a line segment b-b′ in FIG. 7. It has been described that the on-chip lenses 52A and the on-chip lenses 52B have different shapes, and a specific example of the different shapes include an example in which the sizes of the on-chip lenses 52 are different as illustrated in FIG. 8.

In the cross-sectional configuration example of an imaging device 1a (a is added as a first embodiment in order to distinguish from other embodiments) illustrated in FIG. 8, the diameter of an on-chip lens 52Ba arranged on the pixel 2-2-1 is formed to be smaller than the diameter of the on-chip lens 52A arranged on the pixel 2-2-1, for example.

In the imaging device 1a, the period size can be increased by the least common multiple of the structural periods of the on-chip lens 52B and the color filter 51 by forming the period in which the on-chip lens 52B is arranged to be larger than the period of the color filter 51.

As described above, by configuring the on-chip lenses 52Ba having different sizes to be randomly arranged on the pixel array unit 3, it is possible to configure the imaging device 1a capable of suppressing flare and ghost.

### <Configuration of Block>

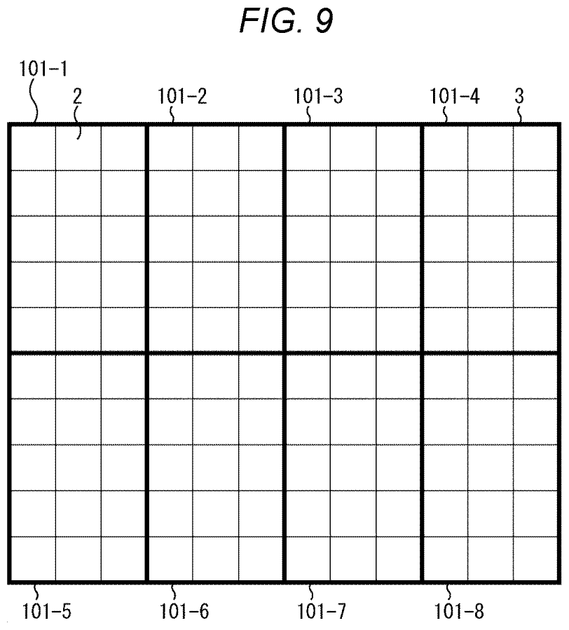

The configuration of the block will be described with reference to FIG. 9. The pixel array unit 3 is divided into a plurality of blocks 101. Note that, for convenience of description, it is described that the pixel array unit 3 is divided into blocks, but the pixel array unit 3 is not physically divided or an interval is not provided.

In the example illustrated in FIG. 9, the pixel array unit 3 is divided into the blocks 101-1 to 101-8. Each block 101 includes 15 pixels 2 of 3×5. As illustrated in FIG. 9, each block 101 has the same shape and the same size.

The on-chip lenses 52B are arranged on the pixels 2 arranged at predetermined positions in the block 101. For example, in a case where the on-chip lenses 52B are arranged in the pixels 2 located at the uppermost left of the block 101-1, the on-chip lenses 52B are arranged in the pixel 2 located at the uppermost left in the block 101 also in the other blocks 101-2 to 101-8.

The number of the on-chip lenses 52B arranged in the block 101 is also the same. For example, in a case where five on-chip lenses 52B are arranged in the block 101-1, five on-chip lenses 52B are arranged in each of the other blocks 101-2 to 101-8.

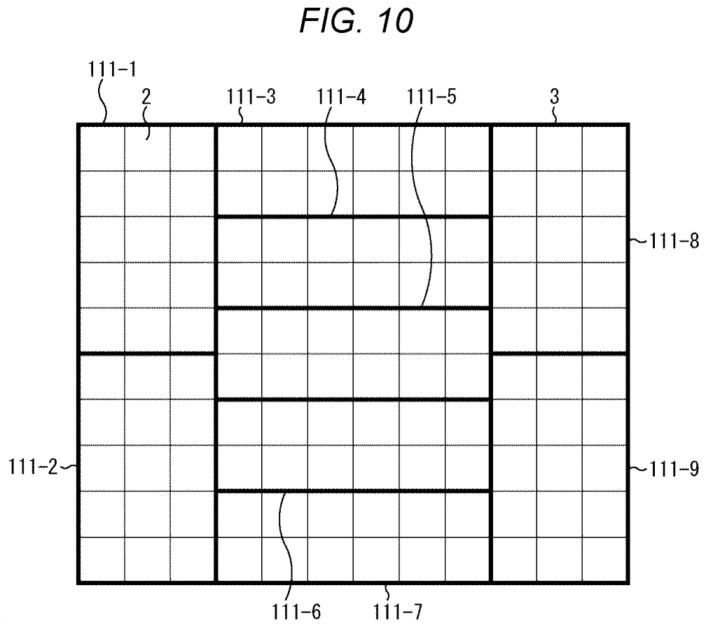

The block 111 may have a shape, a size, and an arrangement as illustrated in FIG. 10. The example illustrated in FIG. 10 is an example in which the pixel array unit 3 is divided into two types of blocks 111. Each of the block 111-1, the block 111-2, the block 111-8, and the block 111-9 is a vertically long block including 15 pixels 2 of 3×5. Blocks 111-3 to 111-7 are horizontally long blocks each including 12 pixels 2 of 6×2.

As illustrated in FIG. 10, blocks 111 having different shapes and blocks 111 having different sizes may be mixed. In the blocks 111 formed in the same shape and size, the on-chip lenses 52B are arranged at the same position in the block 111, and the same number of on-chip lenses 52B are arranged.

For example, five on-chip lenses 52B are arranged in each of the block 111-1, the block 111-2, the block 111-8, and the block 111-9, and one of the on-chip lenses 52B thereof is arranged on the pixel 2 located at the uppermost left in each block 111. Similarly, for example, four on-chip lenses 52B are arranged in each of the blocks 111-3 to 111-7, and one of the on-chip lenses 52B thereof is arranged on the pixel 2 located at the uppermost left of each block 111.

In FIG. 10, the case where two types of blocks 111 are mixed has been described as an example, but two or more types of blocks 111 may be mixed.

Even in a case where a plurality of types of blocks 111 is used, the positions and the number of on-chip lenses 52B arranged in the same type of blocks 111 are the same. This is to facilitate identification of the positions where the on-chip lenses 52B are arranged in a case where the signals from the pixels 2 in which the on-chip lenses 52B are arranged are corrected as described above.

### Effects

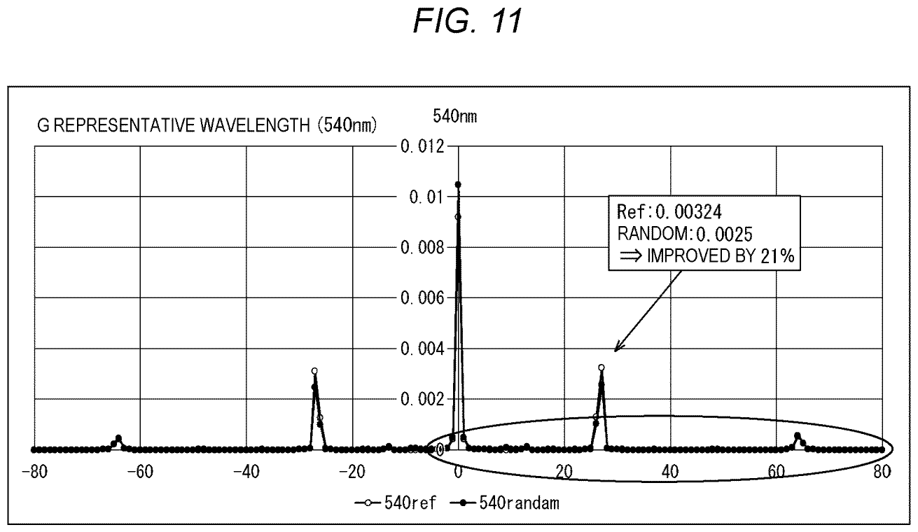

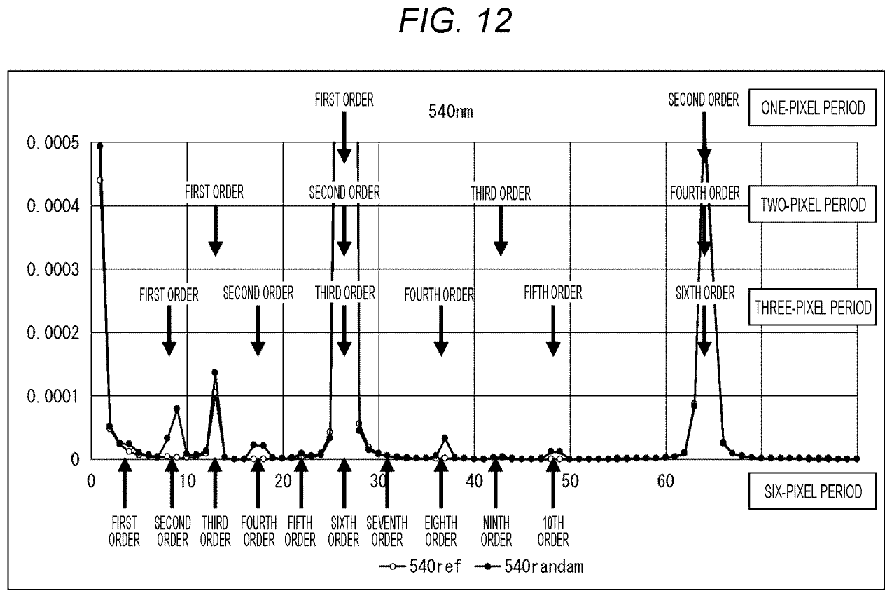

An effect when the on-chip lenses 52B are randomly arranged will be described with reference to FIGS. 11 and 12. FIGS. 11 and 12 are graphs comparing a case where the on-chip lenses 52B are not arranged, that is, a case where the on-chip lenses 52 as illustrated in FIG. 2 are arranged as a reference, with a case where the on-chip lenses 52B are randomly arranged as illustrated in FIG. 7.

In the figure, white circles indicate reference data, and black circles indicate data when the on-chip lenses 52B are randomly arranged. In the reference imaging device 1, as illustrated in FIG. 2, the color filter 51 has a (2×2) period, and the on-chip lens 52 has a (1×1) period.

In the imaging device 1 of the verification target, the color filter 51 has a (2×2) period, and the on-chip lens 52 has a (3×2) period. The (3×2) period of the on-chip lens 52 is a case where the on-chip lens 52B is arranged on one pixel 2 among the 6 pixels 2 of 3×2.

It is data when green light having a wavelength of 540 nm is set as incident light on these imaging devices 1. The horizontal axis of the graph represents the diffraction angle, and the vertical axis represents the intensity of the reflected light.

Referring to the graph illustrated in FIG. 11, it can be seen that there is reflected light in a portion corresponding to the zeroth-order light, the first-order light, and the second-order light. A result was obtained in which the reflection intensity of the reference of the first-order light was 0.00324 and the reflection intensity of the verification target was 0.0025. From this result, it has been confirmed that by randomly arranging the on-chip lenses 52B, the period is increased, and as a result, the reflection intensity is reduced by about 21% and improved.

FIG. 12 is an enlarged graph of a portion surrounded by an ellipse in FIG. 11. In the one-pixel period, it can be seen that reflected light is strongly emitted in portions of the first order and the second order. In the case of the two-pixel period, it can be read that the reflected light is emitted in the first, second, third, and fourth orders, and the angle at which the reflection is emitted is dispersed and the intensity of each reflected light is reduced as compared with the one-pixel period.

Furthermore, in the case of the three-pixel period, it can be read that reflected light is emitted in the first, second, third, fourth, fifth, and sixth orders, and the angle at which reflection is emitted is dispersed and each reflection intensity is reduced as compared with the two-pixel period.

In the case of the six-pixel period, it can be read that the reflected light is emitted in the first to 10th orders, the angle at which the reflection is emitted is dispersed and each reflection intensity is reduced as compared with the three-pixel period.

In the imaging device 1 of the verification target, since the color filter 51 has a (2×2) period and the on-chip lens 52 has a (3×2) period, the period of the light condensing structure is a (6×4) period. In FIG. 12, the data obtained from the imaging device 1 corresponds to the data of the portion of the six-pixel period, and the verification result that the reflected light is generated in the first to 10th orders, but the intensity of the reflected light is small, and the intensity is scattered is obtained. Furthermore, in the six-pixel period, it can also be read that reflected light is generated in portions corresponding to the two-pixel period and the three-pixel period.

As described above, it can be confirmed that the period can be increased, the diffraction angle at which the reflected light is generated can be dispersed, and the intensity of the reflected light per diffraction angle can be weakened by randomly arranging the on-chip lenses 52B. Therefore, it can also be confirmed that occurrence of flare and ghost can be suppressed.

In this manner, by randomly arranging the pixels 2 having different light condensing structures in arrangement of the pixels 2 having the same light condensing structure, occurrence of flare and ghost can be suppressed.

### Second Embodiment

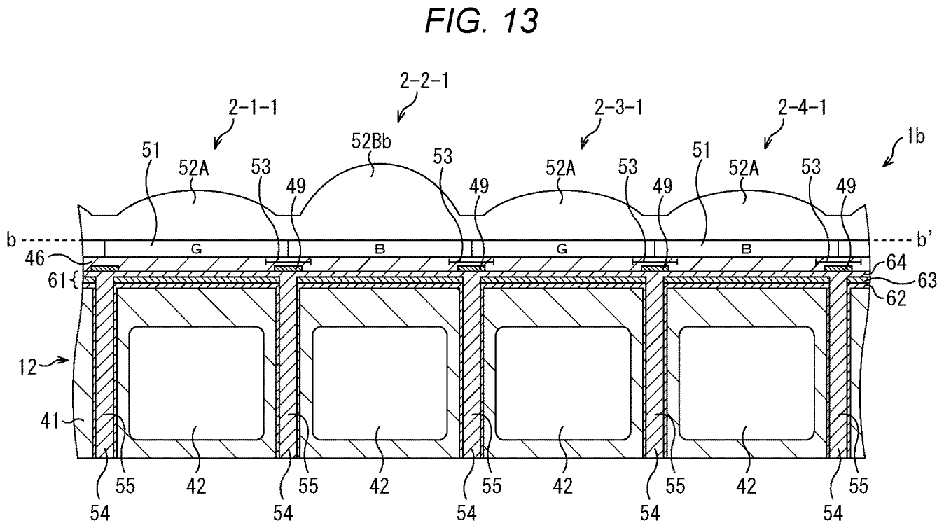

FIG. 13 is a diagram illustrating a cross-sectional configuration example of an imaging device 1b in a second embodiment.

In the following description, the same portions as those of the imaging device 1a in the first embodiment illustrated in FIGS. 7 and 8 are denoted by the same reference signs, and the description thereof will be appropriately omitted. A planar configuration example in the imaging device 1 of the second embodiment and subsequent embodiments is basically the same as the planar configuration example illustrated in FIG. 7, and each embodiment will be described with reference to a cross-sectional configuration example at the line segment b-b′ in FIG. 7.

The imaging device 1b illustrated in FIG. 13 is different from the imaging device 1a illustrated in FIG. 8 in that an on-chip lens 52Bb is formed to be higher in height than the other on-chip lenses 52A, and the other points are similar.

To increase the period, different structures are arranged, with the structures being on-chip lenses 52, and the size of the on-chip lenses 52 is increased in the height direction. In this manner, the height may be changed as the configuration of the on-chip lens 52Bb.

In FIG. 13, the case where the height of the on-chip lens 52Bb is higher than that of the other on-chip lenses 52A has been described as an example, but the on-chip lens may be formed to be lower than that of the other on-chip lenses 52A.

In the imaging device 1b, the period size can be increased by the least common multiple of the structural periods of the on-chip lens 52B and the color filter 51 by forming the period in which the on-chip lens 52B is arranged to be larger than the period of the color filter 51.

### Third Embodiment

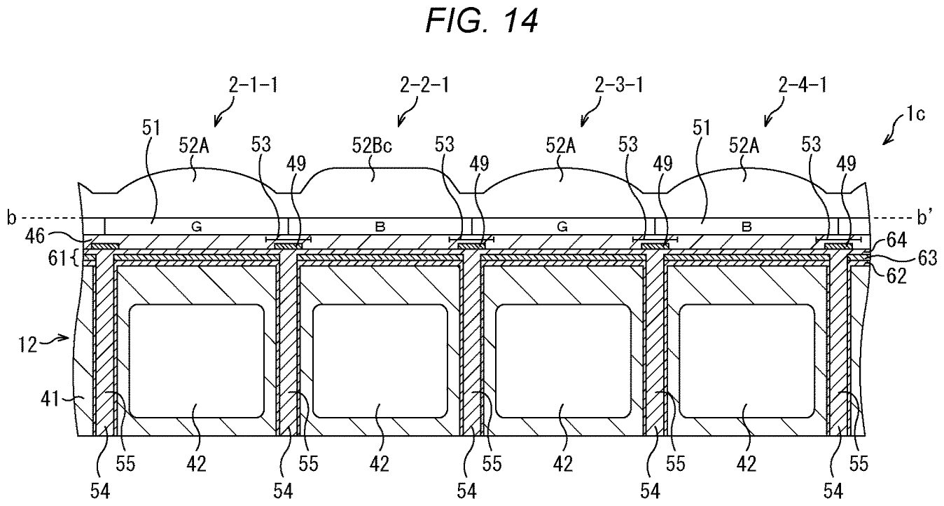

FIG. 14 is a diagram illustrating a cross-sectional configuration example of an imaging device 1c in a third embodiment.

The imaging device 1c illustrated in FIG. 14 is different from the imaging device 1a illustrated in FIG. 8 in that an on-chip lens 52Bc is formed so as to have different flatness as compared with other on-chip lenses 52A, and the other points are similar. In the cross section, the on-chip lens 52Bc illustrated in FIG. 14 is formed in a shape that is partially straight while the other on-chip lenses 52A are circular arcs.

To increase the period, different structures are arranged, with the structures being on-chip lenses 52, and the flatness of these on-chip lenses 52 is configured to be larger than the flatness of the other on-chip lenses 52. In this manner, the flatness may be changed as the configuration of the on-chip lens 52Bc.

In FIG. 14, the case where the flatness of the on-chip lens 52Bc is different from that of the other on-chip lenses 52A has been described as an example. However, the other on-chip lenses 52A may be convex lenses, and the on-chip lens 52Bc may be concave lenses. Furthermore, the on-chip lens 52Bc may be configured as an inner lens.

The on-chip lens 52A and the on-chip lens 52B have the same shape and size, but may be configured to have different materials. The present embodiment also includes a configuration in which the on-chip lens 52B is not formed, in other words, has a flat shape, or the like.

In the first to third embodiments, an example of changing the size and shape of the on-chip lens 52B has been described. As for the shape and size of the on-chip lens 52B, a lens having a desired shape and size can be formed by changing the shape and size of the mask pattern at the time of manufacturing. Furthermore, by dividing the process of manufacturing the on-chip lens 52A and the on-chip lens 52B, the on-chip lenses 52 having different shapes and sizes can be formed.

In the imaging device 1c, the period size can be increased by the least common multiple of the structural periods of the on-chip lens 52B and the color filter 51 by forming the period in which the on-chip lens 52B is arranged to be larger than the period of the color filter 51.

### Fourth Embodiment

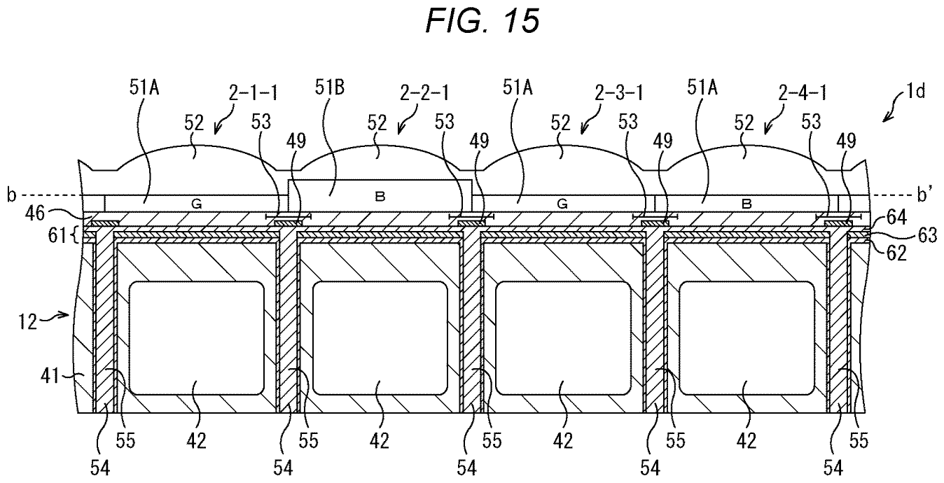

FIG. 15 is a diagram illustrating a cross-sectional configuration example of an imaging device 1d in a fourth embodiment.

The imaging device 1d illustrated in FIG. 15 has a configuration in which color filters 51 having different configurations are randomly arranged. Among the color filters 51 arranged in the pixel array unit 3, the color filter 51 arranged in a large number is described as a color filter 51A, and the color filter 51 arranged in a small number and having a different shape from the other color filters 51 is described as a color filter 51B. In the embodiment described above, the description will be continued on the assumption that the color filter 51A corresponds to the on-chip lens 52A and the color filter 51B corresponds to the on-chip lens 52B.

Among the color filters 51 illustrated in FIG. 15, the color filter 51A is arranged in the pixel 2-1-1, the pixel 2-3-1, and the pixel 2-4-1, and the color filter 51B is arranged in the pixel 2-2-1. The color filter 51B is formed to have a larger film thickness than the color filter 51A.

The coding of the color filter 51 is determined by the specifications, but it is also possible to use color filters 51 of the same color with different pigment concentrations. Therefore, in a case where the transmittances of the color filters 51 are different, it is also possible to adjust the total transmission amount by changing the film thickness, and the film thicknesses of the color filter 51A and the color filter 51B can be configured to be different using such a technology.

Note that, in the example illustrated in FIG. 15, the B (blue) color filter 51 is the color filter 51B, but this description does not indicate that the color filter 51B is a blue color filter. The color filter 51B may have any color, and is a color filter 51 of a color matching an arrangement position randomly arranged.

The color filter 51B may be white (transparent). In addition, the color filter 51B may not be formed, and the transparent insulating film 46 may be formed in a region where the color filter 51 is formed.

To increase the period, different structures are arranged, with the structures being color filters 51, and the thickness of these color filters 51 is made greater than the thickness of the other color filters 51. Note that the color filter 51B may be formed to have a thinner film thickness than the other color filters 51A. As described above, the film thickness may be changed as the configuration of the color filter 51, and the periodicity may be increased.

In the imaging device 1d, the period size can be increased by the least common multiple of the structural periods of the color filter 51 and the on-chip lens 52 by forming the period in which the color filter 51 formed to have a large film thickness is arranged to be larger than the period of the on-chip lens 52.

The fourth embodiment and any one of the first to third embodiments may be combined, and the color filter 51B and the on-chip lens 52B may be randomly arranged. In this case, the color filter 51B and the on-chip lens 52B can be configured to be arranged in the same pixel 2, or can be configured to be arranged in different pixels 2. Furthermore, in this case, since the period can be increased by the color filter 51B and the period can be increased by the on-chip lens 52B, it is possible to further suppress flare and ghost.

### Fifth Embodiment

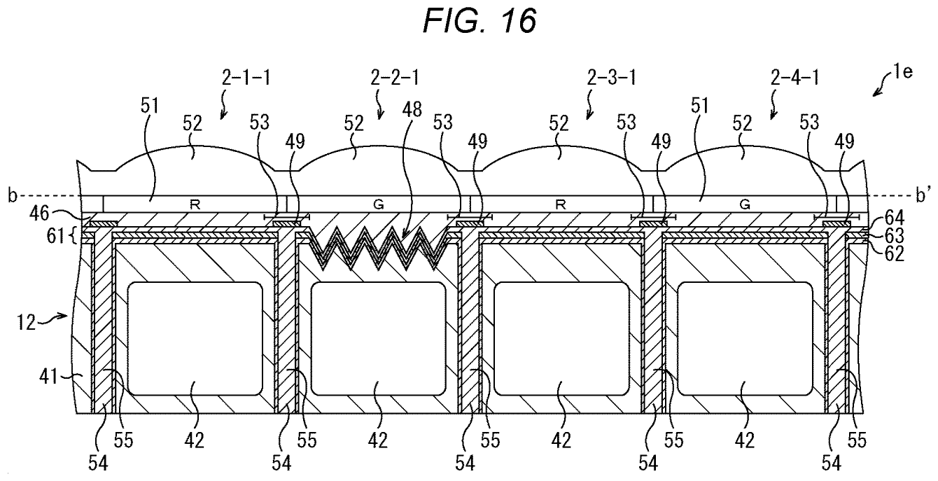

FIG. 16 is a diagram illustrating a cross-sectional configuration example of an imaging device 1e in a fifth embodiment.

In the imaging device 1e illustrated in FIG. 16, an antireflection film 61 provided in some pixels 2 includes a recessed region 48 in which a fine uneven structure is formed. The imaging device 1e illustrated in FIG. 16 has a configuration in which recessed regions 48 are randomly arranged.

The recessed region 48 is a region where fine irregularities are formed. The recessed region 48 is a region having a fine uneven structure formed at an interface (light-receiving-surface-side interface) of the P-type semiconductor region 41 on the upper side of the N-type semiconductor region 42 to be the charge accumulation region.

In the example illustrated in FIG. 16, the recessed region 48 is formed in the pixel 2-2-1, but the recessed region 48 is not formed and the flat antireflection film 61 is formed in the pixel 2-1-1, the pixel 2-3-1, and the pixel 2-4-1.

To increase the period, different structures are arranged, with the structures being recessed regions 48, and the pixels 2 with or without the recessed regions 48 are arranged randomly. As described above, the period can be changed with or without a specific structure.

In the imaging device 1e, the period size can be increased by the least common multiple of the structural periods of the recessed region 48 and the color filter 51 or/and the on-chip lens 52 by forming the period in which the recessed region 48 is arranged to be larger than the period of the color filter 51 or/and the on-chip lens 52.

The fifth embodiment and the fourth embodiment may be combined, and the recessed region 48 and the color filter 51B may be randomly arranged. In this case, the recessed region 48 and the color filter 51B can be configured to be arranged in the same pixel 2, or can be configured to be arranged in different pixels 2. In this case, since the period can be increased in the recessed region 48, and the period can be increased also in the color filter 51B, it is possible to further suppress flare and ghost.

Furthermore, the fifth embodiment and any one of the first to third embodiments may be combined, and the recessed region 48 and the on-chip lens 52B may be randomly arranged. In this case, the recessed region 48 and the on-chip lens 52B can be configured to be arranged in the same pixel 2, or can be configured to be arranged in different pixels 2. Furthermore, in this case, since the period can be increased in the recessed region 48, and the period can also be increased in the on-chip lens 52B, it is possible to further suppress flare and ghost.

Furthermore, the fifth embodiment, the fourth embodiment, and any one of the first to third embodiments may be combined. By randomly arranging different structures such as the recessed region 48, the color filter 51, and the on-chip lens 52, it is possible to further increase the period and to further suppress flare and ghost.

### Sixth Embodiment

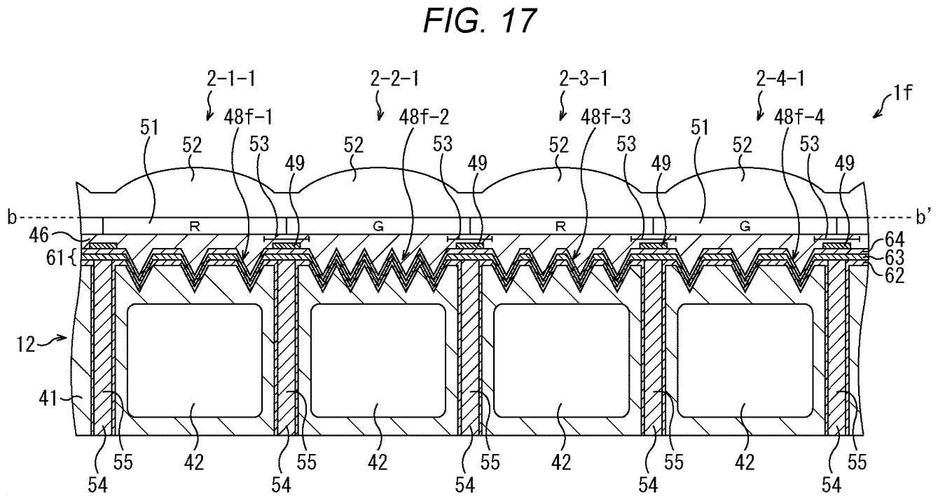

FIG. 17 is a diagram illustrating a cross-sectional configuration example of an imaging device 1f in a sixth embodiment.

The imaging device 1f illustrated in FIG. 17 has a configuration in which the pixel 2 includes recessed regions 48, and the shapes of the provided recessed regions 48 are different.

Three valleys are formed in a recessed region 48f-1 provided in the pixel 2-1-1, five valleys are formed in a recessed region 48f-2 provided in the pixel 2-2-1, four valleys are formed in a recessed region 48f-3 provided in the pixel 2-3-1, and three valleys are formed in a recessed region 48f-4 provided in the pixel 2-4-1. In this manner, the numbers of valleys of the recessed regions 48 may be different, and the recessed regions 48 having different numbers of valleys may be randomly arranged in the pixel array unit 3.

To increase the period, different structures are arranged, with the structures being recessed regions 48, and the pixels 2 with varying numbers of valleys in the recessed regions 48 are arranged randomly. As described above, by changing the shape of a specific structure, it is also possible to achieve a configuration capable of suppressing flare and ghost.

In the imaging device 1f, the period size can be increased by the least common multiple of the structural periods of the recessed region 48 and the color filter 51 or/and the on-chip lens 52 by forming the period in which the recessed region 48 having the same number of valleys (recessed portions) is arranged to be larger than the period of the color filter 51 or/and the on-chip lens 52.

The sixth embodiment can be used in combination with the first to fourth embodiments, and can be applied instead of the fifth embodiment described above.

### Seventh Embodiment

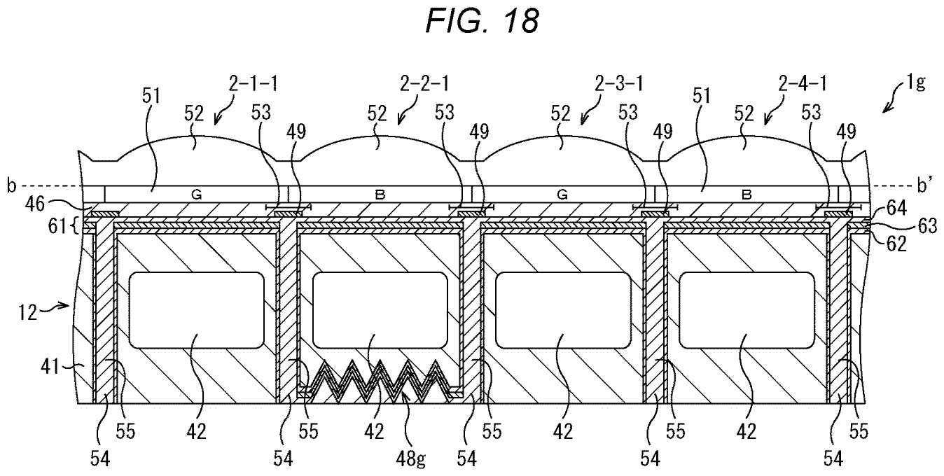

FIG. 18 is a diagram illustrating a cross-sectional configuration example of an imaging device 1g in an eighth embodiment.

The imaging device 1g illustrated in FIG. 18 has a configuration in which the pixels 2 included in the recessed region 48 are randomly arranged on a surface opposite to the light incident surface side and on a surface side where a wiring layer (not illustrated) is arranged. In the example illustrated in FIG. 18, the recessed region 48g is formed in the pixel 2-2-1, but the recessed region 48g is not formed in the pixel 2-1-1, the pixel 2-3-1, and the pixel 2-4-1.

Some of the light incident on the photoelectric conversion region reaches the bottom surface of the photoelectric conversion region and exits to the wiring layer side. In particular, since the light in the infrared wavelength band easily reaches the bottom surface of the photoelectric conversion region, if the recessed region 48f is not formed on the wiring layer side, there is a possibility that the light component passing through to the wiring layer side increases.

As illustrated in FIG. 18, by forming the recessed region 48g on the wiring layer side, light reaching the wiring layer side can be reflected by the recessed region 48g and returned to the photoelectric conversion region. Therefore, it is possible to further increase the amount of light that can be confined in the photoelectric conversion region. By providing the recessed region 48g, particularly in the pixel 2 that handles infrared light (IR) having a long wavelength, the sensitivity can be improved without increasing the thickness of the pixel 2, in other words, the thickness of the semiconductor substrate 12.

In order to control reflected light of light having a long wavelength such as infrared light, it is effective to provide the recessed region 48g on the wiring layer side, and it can also be used as a randomly arranged structure for increasing the period of the light condensing structure.

To increase the period, different structures can be arranged, with the structures being recessed regions 48g, and the pixels 2 with or without the recessed regions 48g can be arranged randomly. As described above, the period can be changed with or without a specific structure.

As in the sixth embodiment illustrated in FIG. 17, the recessed region 48g may be provided for each pixel 2 on the wiring layer side, and the number of valleys of the recessed region 48g provided in each pixel 2 may be configured to be different.

It may be configured such that a large number of pixels 2 in which the recessed region 46g is formed are arranged and a small number of pixels 2 in which the recessed region 46g is not formed are arranged. In this case, the pixels 2 in which the recessed region 46g is not formed are randomly arranged.

In the imaging device 1g, the period size can be increased by the least common multiple of the structural periods of the recessed region 48g and the color filter 51 or/and the on-chip lens 52 by forming the period in which the recessed region 48g is arranged to be larger than the period of the color filter 51 or/and the on-chip lens 52.

The seventh embodiment and the fifth or sixth embodiment may be combined to have a configuration in which the recessed region 48 is formed on both the light incident surface side and the wiring layer side.

It is also possible to combine the seventh embodiment with any one of the first to fourth embodiments, and by combining the seventh embodiment and the first to fourth embodiments, it is possible to increase the number of types of structures randomly arranged in order to increase the period, and it is possible to further increase the period and suppress flare and ghost.

### Eighth Embodiment

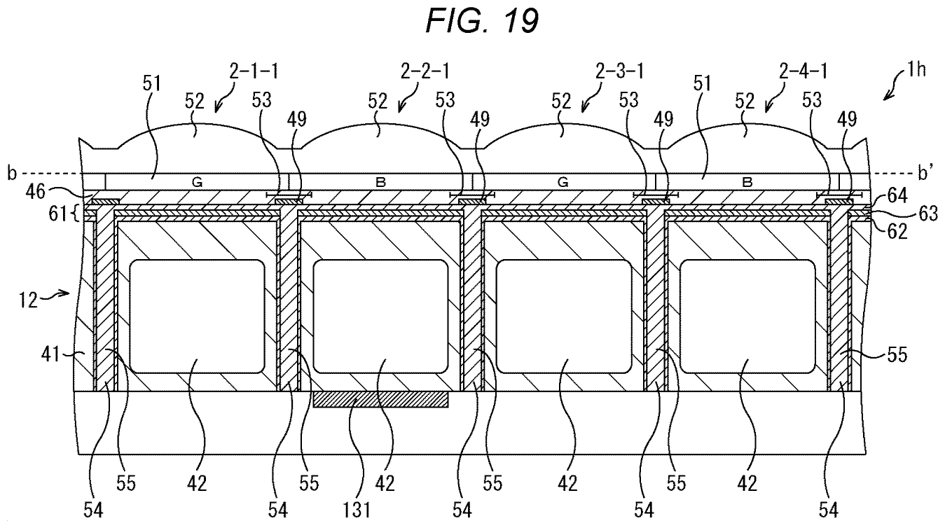

FIG. 19 is a diagram illustrating a cross-sectional configuration example of an imaging device 1h in an eighth embodiment.

The imaging device 1h illustrated in FIG. 19 is a surface opposite to the light incident surface side, is a surface side on which a wiring layer (not illustrated) is arranged, and has a configuration in which the pixels 2 including the reflective film 131 are randomly arranged in the wiring layer. In the example illustrated in FIG. 19, the reflective film 131 is formed in the pixel 2-2-1, but the reflective film 131 is not formed in the pixel 2-1-1, the pixel 2-3-1, and the pixel 2-4-1.

The reflective film 131 can be constituted by a material having light shielding properties, such as tungsten (W) or aluminum (Al). The reflective film 131 can be constituted by a material that reflects light. By forming the reflective film 131, it is possible to prevent light from leaking to the wiring layer side. In addition, similarly to the recessed region 48g of the imaging device 1g in the seventh embodiment illustrated in FIG. 18, light can be returned to the photoelectric conversion region, and photoelectric conversion efficiency can be improved.

Note that, although the reflective film 131 is described, the film may also be constituted by a material that absorbs light, or it may be configured to prevent light from leaking to the wiring layer side by absorbing light.

To increase the period, different structures can be arranged, with the structures being reflective films 131, and the pixels 2 with or without the reflective films 131 can also be arranged randomly. As described above, the period can be changed with or without a specific structure.

It may be configured such that a large number of pixels 2 in which the reflective film 131 is formed are arranged and a small number of pixels 2 in which the reflective film 131 is not formed are arranged. In this case, the pixels 2 on which the reflective film 131 is not formed are randomly arranged.

In the imaging device 1h, the period size can be increased by the least common multiple of the structural periods of the reflective film 131 and the color filter 51 or/and the on-chip lens 52 by forming the period in which the reflective film 131 is arranged to be larger than the period of the color filter 51 or/and the on-chip lens 52.

As in the sixth embodiment illustrated in FIG. 17, the reflective film 131 may be provided for each pixel 2 on the wiring layer side, and the shape and material of the reflective film 131 provided in each pixel 2 may be configured to be different. As the shape of the reflective film 131, for example, the length of the reflective film 131 may be formed to be different. As a difference in material, the reflective film 131 constituted by a material that reflects light and the reflective film 131 constituted by a material that absorbs light may be mixed.

The eighth embodiment and the seventh embodiment may be combined to have a configuration in which the recessed region 48 and the reflective film 131 are formed on the wiring layer side.

The eighth embodiment and the fifth or sixth embodiment may be combined to have a configuration in which the recessed region 48 is formed on the light incident surface side and the reflective film 131 is formed on the wiring layer side.

It is also possible to combine the eighth embodiment with any one of the first to fourth embodiments, and by combining the eighth embodiment and the first to fourth embodiments, it is possible to increase the number of types of structures randomly arranged in order to increase the period, and it is possible to further increase the period and suppress flare and ghost.

### Ninth Embodiment

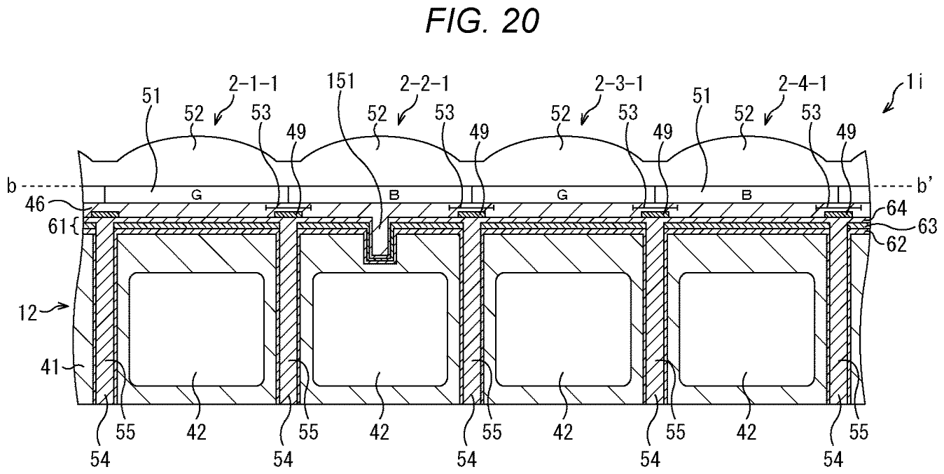

FIG. 20 is a diagram illustrating a cross-sectional configuration example of an imaging device 1i in a ninth embodiment.

In the imaging device 1i illustrated in FIG. 20, trenches 151 are randomly arranged. In the example illustrated in FIG. 20, the trench 151 is formed in the pixel 2-2-1, but the trench 151 is not formed in the pixel 2-1-1, the pixel 2-3-1, and the pixel 2-4-1.

The trench 151 provided in the pixel 2-2-1 is formed in a quadrangular shape as illustrated in FIG. 20 in a cross-sectional view. The depth of the trench 151 is up to a position not reaching the N-type semiconductor region 42, and is a recessed member formed in the P-type semiconductor region 41.

The trench 151 is an interface between the antireflection film 61 and the transparent insulating film 46, and is formed in a shape having a recess in the depth direction with reference to the surface on which the light shielding film 49 is formed.

By providing the trench 151, an optical path length of the light incident on the pixel 2 can be gained. The light incident on the pixel 2 is incident on the N-type semiconductor region 42 (photodiode) while repeating reflection such as reflection on a side surface of the trench 151 and reflection on a side surface of the inter-pixel isolation portion 54 at an opposing position. As the reflection is repeated, the optical path length becomes long, so that even light having a long wavelength such as near-infrared light can be efficiently absorbed, for example.

To increase the period, different structures can be arranged, with the structures being trenches 151, and the pixels 2 with or without the trenches 151 can also be arranged randomly. As described above, the period can be changed with or without a specific structure.

It may be configured such that a large number of pixels 2 in which the trench 151 is formed are arranged and a small number of pixels 2 in which the trench 151 is not formed are arranged. In this case, the pixels 2 in which the trench 151 is not formed are randomly arranged.

In a cross-sectional view, the number of trenches 151 may be different. Although one trench 151 is formed in the pixel 2-2-1 illustrated in FIG. 20 in the cross-sectional view, for example, the pixels 2 having different numbers of trenches 151 may be randomly arranged such that two trenches 151 are formed in the pixel 2-1-1 and four trenches 151 are formed in the pixel 2-3-1.

The trenches 151 having different depths may be randomly arranged.

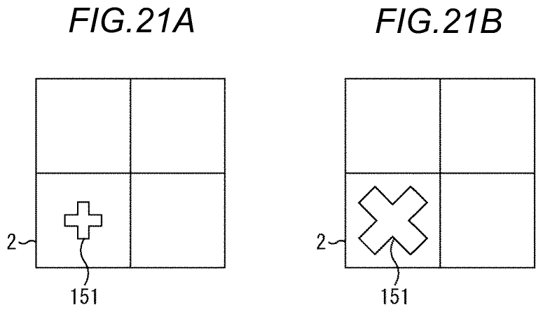

FIG. 21 is a diagram for explaining the shape and size of the trench 151 in plan view of the pixel 2. As illustrated in FIG. 21, the shape of the trench 151 can be + or ×. For example, in A of FIG. 21, the trench 151 has a + shape in plan view, but in B of FIG. 21, + is slightly inclined and has a × shape. In this manner, even with the same shape, different inclinations can create varying shapes, allowing them to be used as randomly arranged structures to increase the period.

The trench 151 illustrated in B of FIG. 21 is formed to be larger than the trench 151 illustrated in A of FIG. 21. In this manner, the trenches 151 having different sizes may be randomly arranged in the pixel array unit 3.

To increase the period, different structures can be arranged, with the structures being trenches 151, and the shape, size, number, and the like of these trenches 151 can be varied.

In the imaging device 1i, the period size can be increased by the least common multiple of the structural periods of the trench 151 and the color filter 51 or/and the on-chip lens 52 by forming the period in which the trench 151 is arranged to be larger than the period of the color filter 51 or/and the on-chip lens 52.

The ninth embodiment with the seventh or/and eighth embodiments may be combined to have a configuration in which the recessed region 48 and the reflective film 131 are formed on the wiring layer side.

It is also possible to combine the ninth embodiment with any one of the first to eighth embodiments, and by combining the ninth embodiment with any one of the first to eighth embodiments, it is possible to increase the number of types of structures randomly arranged in order to increase the period, and it is possible to further increase the period and suppress flare and ghost.

### <Application Example to Electronic Apparatus>

The present technology can be applied to general electronic apparatuses using an imaging element in an image capturing unit (photoelectric conversion unit), such as an imaging device such as a digital still camera or a video camera, a mobile terminal device having an imaging function, and a copying machine using an imaging element in an image reading unit. An imaging element may be formed as one chip, or may be in a modular form having an imaging function in which an imaging unit and a signal processing unit or an optical system are packaged together.

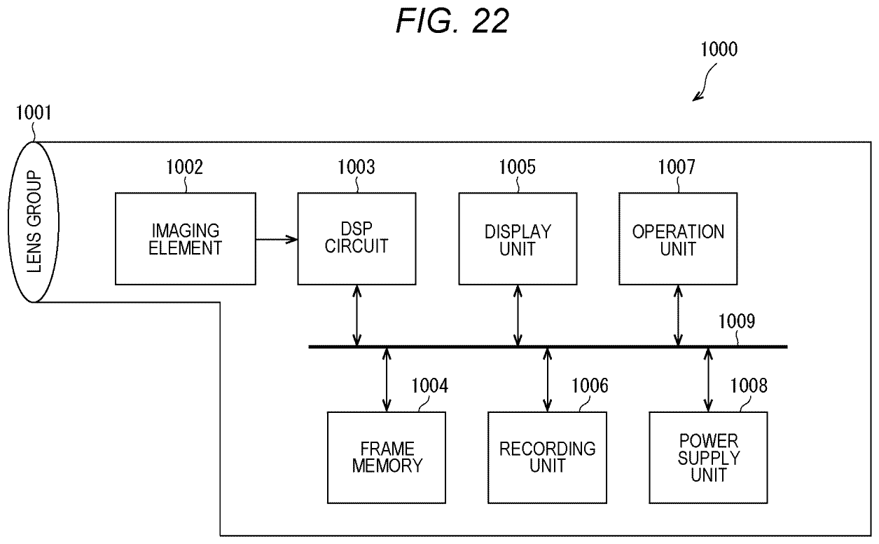

FIG. 22 is a block diagram illustrating a configuration example of an imaging device as an electronic apparatus to which the present technology is applied.

An imaging element 1000 in FIG. 22 includes an optical unit 1001 including a lens group and the like, an imaging element (imaging device) 1002, and a digital signal processor (DSP) circuit 1003 that is a camera signal processing circuit. In addition, the imaging element 1000 also includes a frame memory 1004, a display unit 1005, a recording unit 1006, an operation unit 1007, and a power supply unit 1008. The DSP circuit 1003, the frame memory 1004, the display unit 1005, the recording unit 1006, the operation unit 1007, and the power supply unit 1008 are connected to one another via a bus line 1009.

The optical unit 1001 captures incident light (image light) from a subject, and forms an image on the imaging surface of the imaging element 1002. The imaging element 1002 converts the light amount of the incident light formed on the imaging surface by the optical unit 1001 into an electrical signal in units of pixels and outputs the electrical signal as a pixel signal.

The display unit 1005 is formed with a flat-panel display such as a liquid crystal display (LCD) or an organic electro luminescence (EL) display, for example, and displays a moving image or a still image formed by the imaging element 1002. The recording unit 1006 records the moving image or the still image captured by the imaging element 1002 in a recording medium such as a hard disk or a semiconductor memory.

The operation unit 1007 issues operation commands for various functions of the imaging element 1000, being operated by the user. The power supply unit 1008 appropriately supplies various kinds of power that is the operating power supply for the DSP circuit 1003, the frame memory 1004, the display unit 1005, the recording unit 1006, and the operation unit 1007, to these supply targets.

The imaging device 1 according to the first to ninth embodiments can be applied to a part of the imaging device illustrated in FIG. 22.

### <Application Example to Endoscopic Surgery System>

The technology according to the present disclosure (the present technology) can be applied to various products. For example, the technology according to the present disclosure may be applied to an endoscopic surgery system.

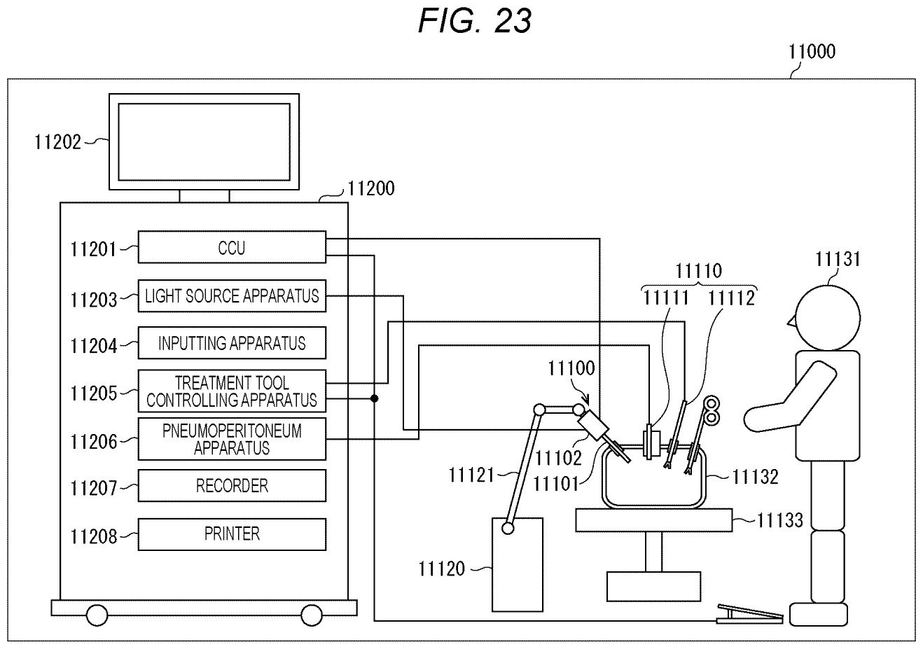

FIG. 23 is a view depicting an example of a schematic configuration of an endoscopic surgery system to which the technology according to an embodiment of the present disclosure (present technology) can be applied.

In FIG. 23, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be output is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

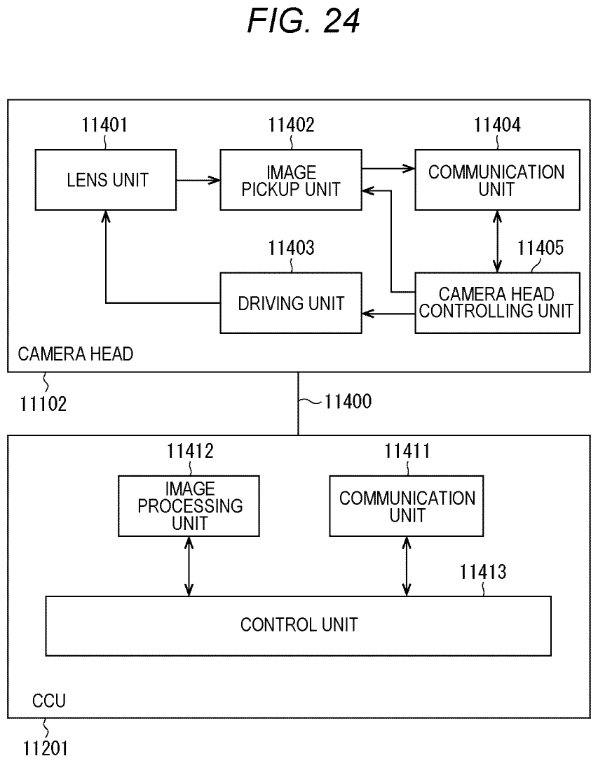

FIG. 24 is a block diagram depicting an example of a functional configuration of the camera head 11102 and the CCU 11201 depicted in FIG. 23.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

### <Application Example to Mobile Body>

The technology according to the present disclosure (the present technology) can be applied to various products. For example, the technology according to the present disclosure may be achieved in the form of a device to be mounted on a mobile body of any kind, such as an automobile, an electric vehicle, a hybrid electric vehicle, a motorcycle, a bicycle, a personal mobility, an airplane, a drone, a vessel, or a robot.

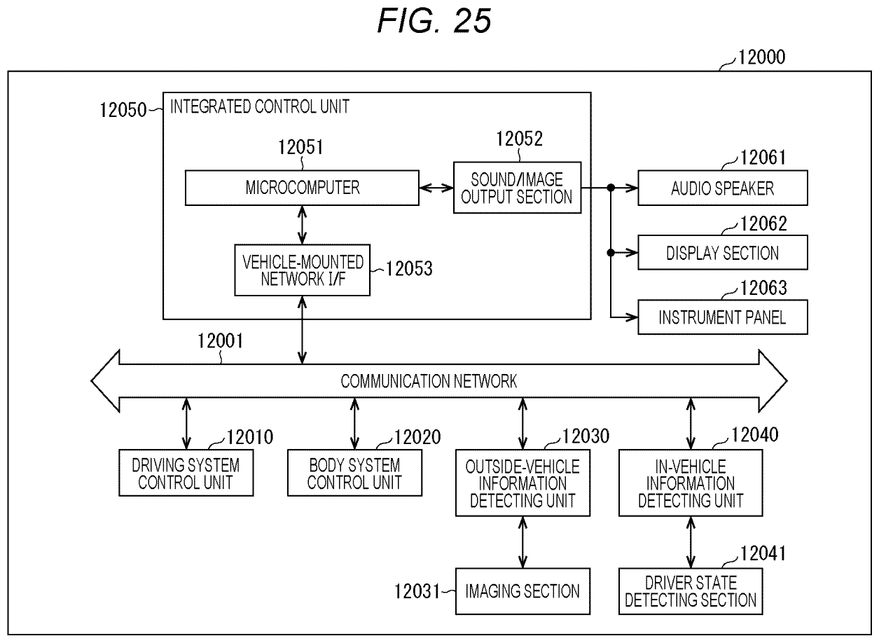

FIG. 25 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 25, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 25, an audio speaker 12061, a display section 12062, and an instrument panel 12063 are illustrated as the output device. The display section 12062 may, for example, include at least one of an on-board display and a head-up display.

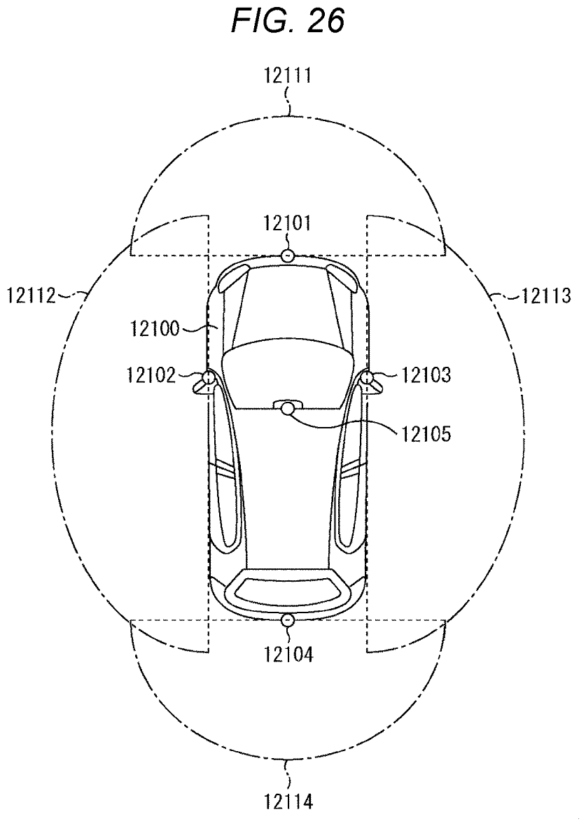

FIG. 26 is a diagram depicting an example of the installation position of the imaging section 12031.

In FIG. 26, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 26 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

In the present specification, the system represents the entire device including a plurality of devices.

Note that the effects described in the present specification are merely examples and are not limited, and other effects may be provided.

Note that the embodiments of the present technology are not limited to the above-described embodiments, and various changes can be made without departing from the gist of the present technology.

Note that the present technology can also have the following configurations.

(1)

A photodetection device including:
a photoelectric conversion unit;
a first pixel including a first light condensing unit that condenses light on the photoelectric conversion unit;
a second pixel including a second light condensing unit having a shape different from a shape of the first light condensing unit; and
a pixel array unit in which the first pixel and the second pixel are arranged in a matrix,
in which the second pixel is randomly arranged in the pixel array unit.
   (2)

The photodetection device according to (1),
in which the light condensing unit includes an on-chip lens, and
the on-chip lens included in the second light condensing unit is formed to have a size, a height, or a flatness different from those of the on-chip lens included in the first light condensing unit.
   (3)

The photodetection device according to (1) or (2),
in which the light condensing unit includes a color filter, and
the color filter included in the second light condensing unit is different in film thickness or material from the color filter included in the first light condensing unit.
   (4)

The photodetection device according to any one of (1) to (3),
in which the second light condensing unit includes a recessed region having a plurality of recessed portions on a light incident surface side, and the first light condensing unit does not include the recessed region.
   (5)

The photodetection device according to any one of (1) to (3),
in which the first light condensing unit and the second light condensing unit each include a recessed region having a plurality of recessed portions on a light incident surface side, and
the number of recessed portions in the recessed region included in the first light condensing unit is different from the number of recessed portions in the recessed region included in the second light condensing unit.
   (6)

The photodetection device according to any one of (1) to (5),
in which the second light condensing unit includes a recessed region having a plurality of recessed portions on a wiring layer side, and the first light condensing unit does not include the recessed region.
   (7)

The photodetection device according to any one of (1) to (6),
in which the second light condensing unit includes a film that reflects or absorbs light on a wiring layer side, and the first light condensing unit does not include the film.
   (8)

The photodetection device according to any one of (1) to (7),
in which each of the first light condensing unit and the second light condensing unit includes a recessed region having a recessed portion provided on a light incident surface side in a cross-sectional view, and
a shape of the recessed region included in the first light condensing unit and a shape of the recessed region included in the second light condensing unit are different in plan view.
   (9)

A photodetection device including:
a photoelectric conversion unit;
a light condensing unit that condenses light on the photoelectric conversion unit;
a pixel including the light condensing unit; and
a pixel array unit in which the pixels are arranged in a matrix,
in which the light condensing unit includes a first member and a second member,
a first period in which the first member is arranged and a second period in which the second member is arranged are different in the pixel array unit, and
the second period is longer than the first period.
   (10)

The photodetection device according to (9),
in which the first member is a color filter,
the second member is an on-chip lens,
the on-chip lens includes a first on-chip lens and a second on-chip lens formed with a size, a height, or a flatness different from those of the first on-chip lens, and
the second period is a period in which the second on-chip lens is arranged.
   (11)

The photodetection device according to (9) or (10),
in which the first member is an on-chip lens,
the second member is a color filter,
the color filter includes a first color filter and a second color filter having a film thickness or a material different from that of the first color filter, and
the second period is a period in which the second color filter is arranged.
   (12)

The photodetection device according to any one of (9) to (11),
in which the first member is a color filter or an on-chip lens,
the second member is a recessed region having a plurality of recessed portions provided on a light incident surface side, and
the second period is a period in which the recessed region is arranged.
   (13)

The photodetection device according to any one of (9) to (12),
in which the first member is a color filter or an on-chip lens,
the second member is a recessed region having a plurality of recessed portions provided on a wiring layer side, and
the second period is a period in which the recessed region is arranged.
   (14)

The photodetection device according to any one of (9) to (13),
in which the first member is a color filter or an on-chip lens,
the second member is a film that reflects or absorbs light on a wiring layer side, and
the second period is a period in which the film is arranged.

### REFERENCE SIGNS LIST

1 Imaging device
2 Pixel
3 Pixel array unit
4 Vertical drive circuit
5 Column signal processing circuit
6 Horizontal drive circuit
7 Output circuit
8 Control circuit
9 Vertical signal line
10 Pixel drive line
11 Horizontal signal line
12 Semiconductor substrate
13 Input/output terminal
41 Semiconductor region
42 N-type semiconductor region
46 Transparent insulating film
48 Recessed region
49 Light shielding film
51 Color filter
52 On-chip lens
54 Inter-pixel isolation portion
55 Insulator
61 Antireflection film
62 Hafnium oxide film
63 Aluminum oxide film
64 Silicon oxide film
81 Seal glass
82 Infrared cut filter
101 Block
111 Block
131 Reflective film
151 Trench

What is claimed is:

1. A photodetection device comprising:
a photoelectric conversion unit;
a first pixel including a first light condensing unit that condenses light on the photoelectric conversion unit;
a second pixel including a second light condensing unit having a shape different from a shape of the first light condensing unit; and
a pixel array unit in which the first pixel and the second pixel are arranged in a matrix,
wherein the second pixel is randomly arranged in the pixel array unit.

2. The photodetection device according to claim 1,
wherein the light condensing unit includes an on-chip lens, and
the on-chip lens included in the second light condensing unit is formed to have a size, a height, or a flatness different from those of the on-chip lens included in the first light condensing unit.

3. The photodetection device according to claim 1,
wherein the light condensing unit includes a color filter, and
the color filter included in the second light condensing unit is different in film thickness or material from the color filter included in the first light condensing unit.

4. The photodetection device according to claim 1,
wherein the second light condensing unit includes a recessed region having a plurality of recessed portions on a light incident surface side, and the first light condensing unit does not include the recessed region.

5. The photodetection device according to claim 1,
wherein the first light condensing unit and the second light condensing unit each include a recessed region having a plurality of recessed portions on a light incident surface side, and
the number of recessed portions in the recessed region included in the first light condensing unit is different from the number of recessed portions in the recessed region included in the second light condensing unit.

6. The photodetection device according to claim 1,
wherein the second light condensing unit includes a recessed region having a plurality of recessed portions on a wiring layer side, and the first light condensing unit does not include the recessed region.

7. The photodetection device according to claim 1,
wherein the second light condensing unit includes a film that reflects or absorbs light on a wiring layer side, and the first light condensing unit does not include the film.

8. The photodetection device according to claim 1,
wherein each of the first light condensing unit and the second light condensing unit includes a recessed region having a recessed portion provided on a light incident surface side in a cross-sectional view, and
a shape of the recessed region included in the first light condensing unit and a shape of the recessed region included in the second light condensing unit are different in plan view.

9. A photodetection device comprising:
a photoelectric conversion unit;
a light condensing unit that condenses light on the photoelectric conversion unit;
a pixel including the light condensing unit; and
a pixel array unit in which the pixels are arranged in a matrix,
wherein the light condensing unit includes a first member and a second member,
a first period in which the first member is arranged and a second period in which the second member is arranged are different in the pixel array unit, and
the second period is longer than the first period.

10. The photodetection device according to claim 9,
wherein the first member is a color filter,
the second member is an on-chip lens,
the on-chip lens includes a first on-chip lens and a second on-chip lens formed with a size, a height, or a flatness different from those of the first on-chip lens, and
the second period is a period in which the second on-chip lens is arranged.

11. The photodetection device according to claim 9,
wherein the first member is an on-chip lens,
the second member is a color filter,
the color filter includes a first color filter and a second color filter having a film thickness or a material different from that of the first color filter, and
the second period is a period in which the second color filter is arranged.

12. The photodetection device according to claim 9,
wherein the first member is a color filter or an on-chip lens,
the second member is a recessed region having a plurality of recessed portions provided on a light incident surface side, and
the second period is a period in which the recessed region is arranged.

13. The photodetection device according to claim 9,
wherein the first member is a color filter or an on-chip lens,
the second member is a recessed region having a plurality of recessed portions provided on a wiring layer side, and
the second period is a period in which the recessed region is arranged.

14. The photodetection device according to claim 9,
wherein the first member is a color filter or an on-chip lens,
the second member is a film that reflects or absorbs light on a wiring layer side, and
the second period is a period in which the film is arranged.
